(19) United States
(12) Patent Application Publication
(10) Pub. No.: US 2017/0190160 A1
(43) Pub. Date: Jul. 6, 2017

(54) Frame for Aiding in Screen Protector Application

(71) Applicant: Robin Peng, Sandy, UT (US)

(72) Inventor: Robin Peng, Sandy, UT (US)

(21) Appl. No.: 15/396,088

(22) Filed: Dec. 30, 2016

Related U.S. Application Data
(60) Provisional application No. 62/272,864, filed on Dec. 30, 2015.

(51) Int. Cl. B32B 37/00; B32B 37/10; H05K 5/03

(52) U.S. Cl. CPC B32B 37/0046; H05K 5/03; B32B 37/10

(57) ABSTRACT

A system and method for applying a screen protector to a handheld electronic device may provide a frame to surround the device and secure a screen protector over the device prior to final installation. The frame may provide supports to interface with screen protector cutouts to ensure a uniform fit. For rigid protectors, sets of small teeth may secure the protector to the frame and provide audible confirmation of proper mounting and eventual installation. When fitted over a device, a user may then push the screen protector downward for a perfect mounting of the protector to the device every time.

### CROSS-REFERENCES TO RELATED APPLICATIONS

This Application claims priority as a non-provisional perfection of prior filed U.S. Application 62/272,864, filed Dec. 30, 2015, and incorporates the same by reference herein in its entirety.

### FIELD OF THE INVENTION

The present invention relates to the field of consumer electronics and more particularly relates to an apparatus used to apply protective films to consumer electronics and a method for applying the same.

### BACKGROUND OF THE INVENTION

Consumer electronics have become ubiquitous in our modern society. They have not only become common, but also serve to connect us together in ways seemingly unimaginable even 50 years ago. Modern consumer electronics, however, suffer many of the same flaws. First among those flaws is that they are fragile, easily scratched or damaged. Many personal electronics now use a display screen, usually an LCD-type screen, in which to display information to the user. Often, these screens are capacitive and are utilized as an input system for the electronic device. These screens are notoriously fragile and easily scratched. Consumer electronic devices tend to also use some form of buttons and have shells which are assembled from multiple pieces, all of which leave space for environmental elements, like water, access to the delicate internal components.

One solution to the above problems is the use of a screen protector over the display screen and buttons on the front face of the device. Screen protectors are sheets of a protective film, hardened glass, or other material which are applied to the surface of a touchscreen. These screen protectors form a reasonable barrier that not only prevents access by the elements through those areas, but also serve as a barrier to prevent scratches on the most delicate part of the device—the screen. While effective, these protectors must be positioned over the screen and device perfectly to ensure an effective fit. Different protectors are also needed for different devices. The protectors tend to use adhesives which can ruin the protector if it is applied incorrectly and it is needed to be removed. Even when a protector can be salvaged from a misapplication, there is a high time commitment to apply the protector correctly. What is needed then, is a system that would cut the time necessary to accurately apply many different protectors to many different devices while reducing the possibility for error and associated waste.

The present invention is an apparatus and method for applying rigid screen protectors to consumer electronic devices, such as mobile phones, music players, hand-held tablets, and any mobile communication device with a screen. Rigid partial frames are known in the art, but being partial frames they are still susceptible to misplacement of the screen protector and do not employ a ready and sure release of the protector onto the device. The present invention represents a departure from the prior art in that the system and associated apparatus of the present invention allows for quick, efficient, and accurate application of protective covers to many different brands and styles of consumer electronic devices.

### SUMMARY OF THE INVENTION

In view of the foregoing disadvantages inherent in the application of screen protectors to consumer electronics, this invention provides an apparatus that is precise in the application of a screen protector to a device and thereby cuts the time necessary to apply such protectors and reduces waste. As such, the present invention's general purpose is to provide a new and improved screen protector application apparatus that is easily adaptable to different devices while easy and efficient to use.

To accomplish these objectives, a cover installation apparatus and method may comprise a frame designed to fit about an electronic device, such as a phone. The frame also contains a screen protector. The frame may then be positionable over the device while securely holding the protector above the surface of the device. The protector may then gently be pushed downward against the surface of the device in a manner to lessen bubbles or other defective errors. Features in the frame may be provided to automatically center the protector over the phone. Likewise, other features may provide user feedback and further secure the protector in the frame until installed.

The more important features of the invention have thus been outlined in order that the more detailed description that follows may be better understood and in order that the present contribution to the art may better be appreciated. Additional features of the invention will be described hereinafter and will form the subject matter of the claims that follow.

Many objects of this invention will appear from the following description and appended claims, reference being made to the accompanying drawings forming a part of this specification wherein like reference characters designate corresponding parts in the several views.

Before explaining at least one embodiment of the invention in detail, it is to be understood that the invention is not limited in its application to the details of construction and the arrangements of the components set forth in the following description or illustrated in the drawings. The invention is capable of other embodiments and of being practiced and carried out in various ways. Also, it is to be understood that the phraseology and terminology employed herein are descriptive and should not be regarded as limiting.

As such, those skilled in the art will appreciate that the conception, upon which this disclosure is based, may readily be utilized as a basis for the designing of other structures, methods and systems for carrying out the several purposes of the present invention. It is important, therefore, that the claims be regarded as including such equivalent constructions insofar as they do not depart from the spirit and scope of the present invention.

### BRIEF DESCRIPTION OF THE DRAWINGS

FIG. 1 is an exploded view of the system and a compatible phone.

FIG. 2 is an alternate exploded view of the system and phone of FIG. 1.

FIG. 3 is a perspective view of the system assembled and a compatible phone.

FIG. 4 is a close-up of the system of FIG. 3, taken in circle A.

FIG. 5 is an alternate perspective view of the system assembled and a compatible phone.

FIG. 6 is a close-up of the system of FIG. 5, taken in circle B.

FIG. 7 is a perspective view of the system positioned over the compatible phone.

FIG. 8 is a side elevation of the system and phone of FIG. 7.

FIG. 9 is a partial sectional view of the system and phone of FIG. 7.

FIGS. 10-18 are perspective views depicting steps in the method.

### DETAILED DESCRIPTION OF THE PREFERRED EMBODIMENT

With reference now to the drawings, the preferred embodiment of the screen protector application system and method is herein described. It should be noted that the articles “a”, “an”, and “the”, as used in this specification, include plural referents unless the content clearly dictates otherwise.

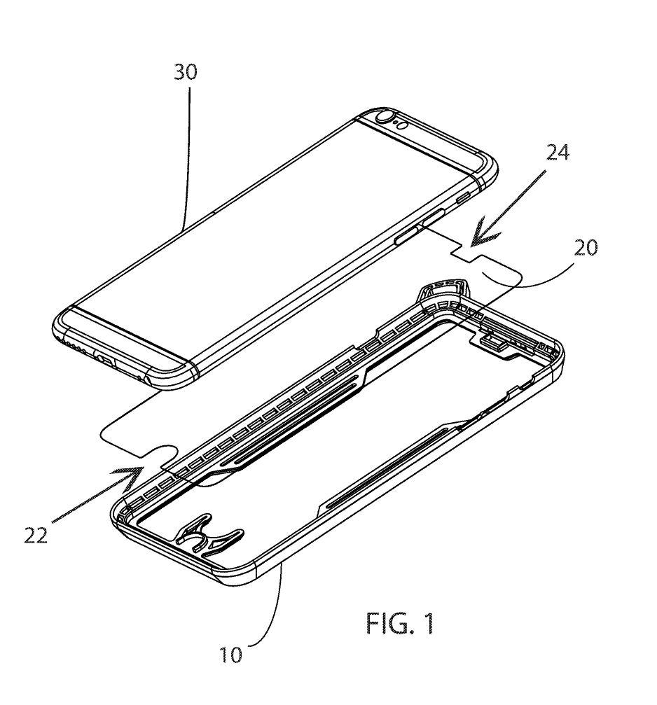

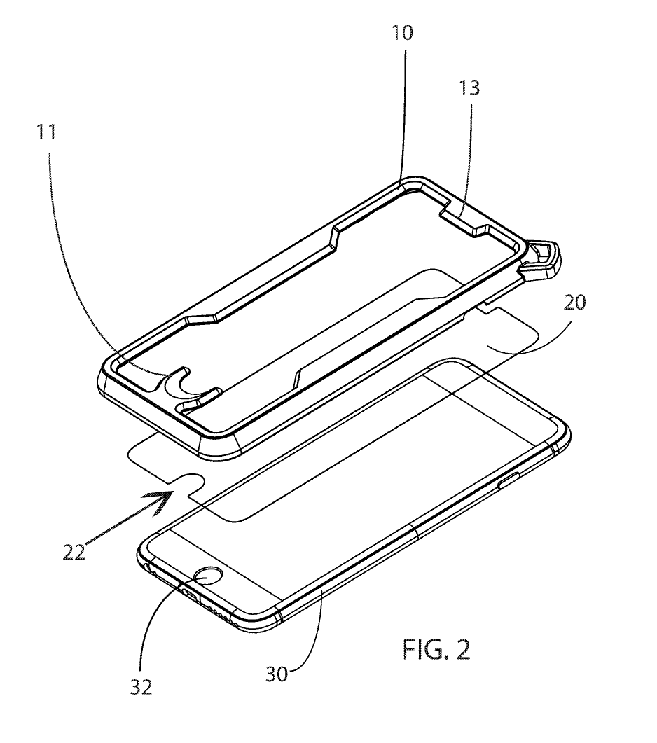

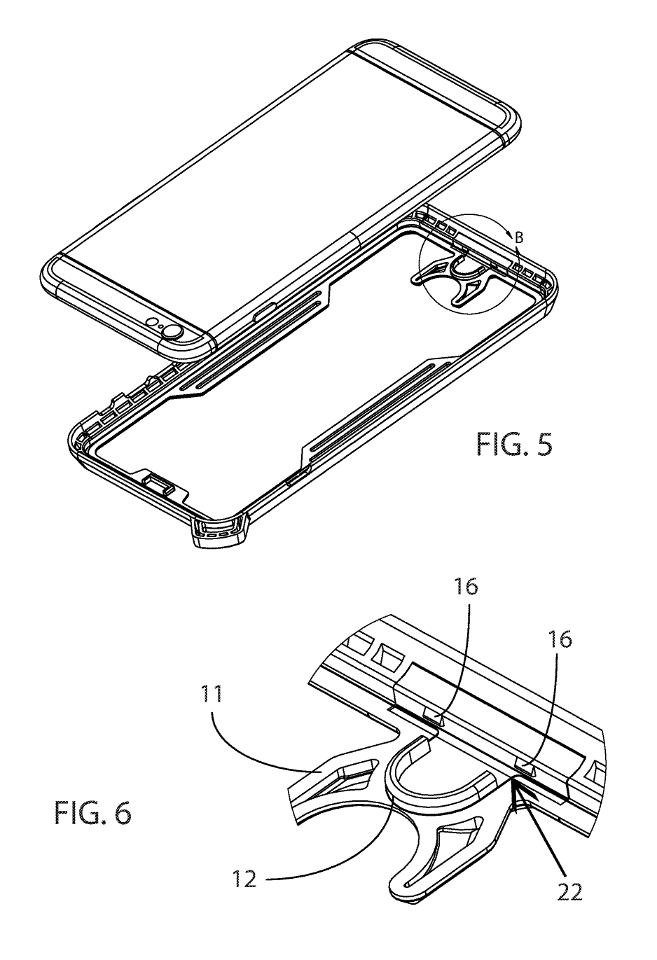

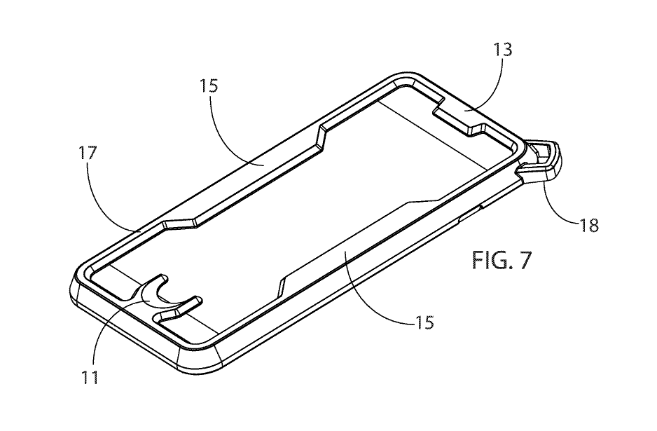

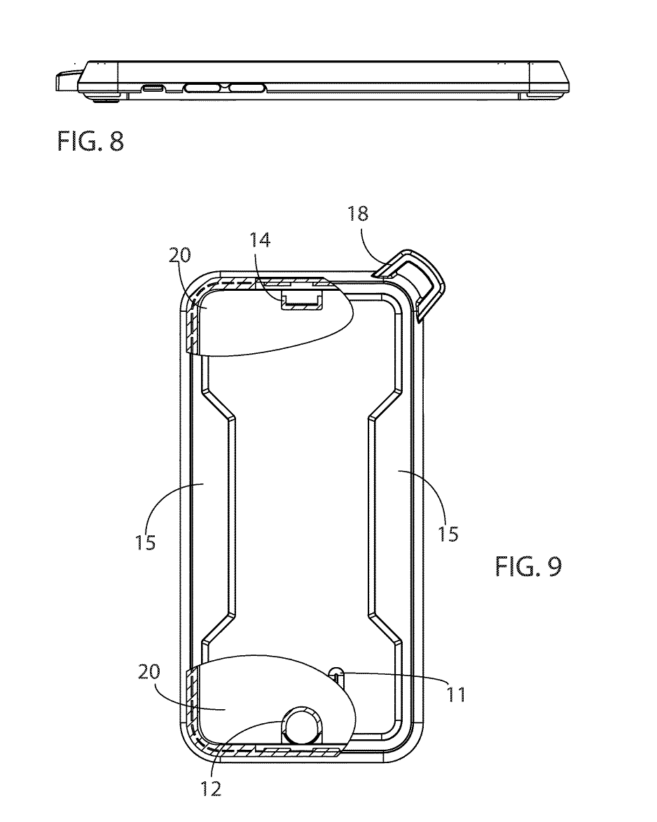

With reference to FIGS. 1-9, the system has two basic components, a frame 10 and a screen protector 20. Screen protector 20 is designed to fit on a given device, such as phone 30, tablet, music player or other device, and has appropriate cut-outs (notches or holes) 22,24 to fit around device components such as microphones, cameras, speakers, sensors, or buttons 32. Ideally, the screen protector 20 also has some rigidity. Frame 10 is also constructed to comport with the device structures and general shape as it must fit over the device 30 for installation of the screen protector 20, as is shown in FIGS. 7-9.

The frame has many useful features to assist in the precise installation of a screen protector 20 onto a device 30. It should be noted that the screen protector 20 and frame 10 are made to ensure a consistent fit between the frame 10 and each new screen protector 20. Likewise, when the frame is installed over a device 30, the device 30 is held in the same orientation as any other similar device held by the frame 10. This uniformity allows positioning of the screen protector 20 to also be uniform in relation to the device 30 in each application. Therefore, it is easily appreciated that the screen protector 20 and frame 10 may be designed to precisely position the screen protector 20 over the device and minimize human error in application. It is also readily appreciated that different frames will be needed for different devices, just as there are currently different screen protectors cut, shaped and sized for different devices. These differences would even encompass curved protectors for current “edge” phones. Accordingly, the depicted frame 10, protector 20, and device 30 should all be considered exemplary and only showing one singular embodiment of the invention and that any shape of protector and frame may be made for any electronic device for which a screen protector may be useful.

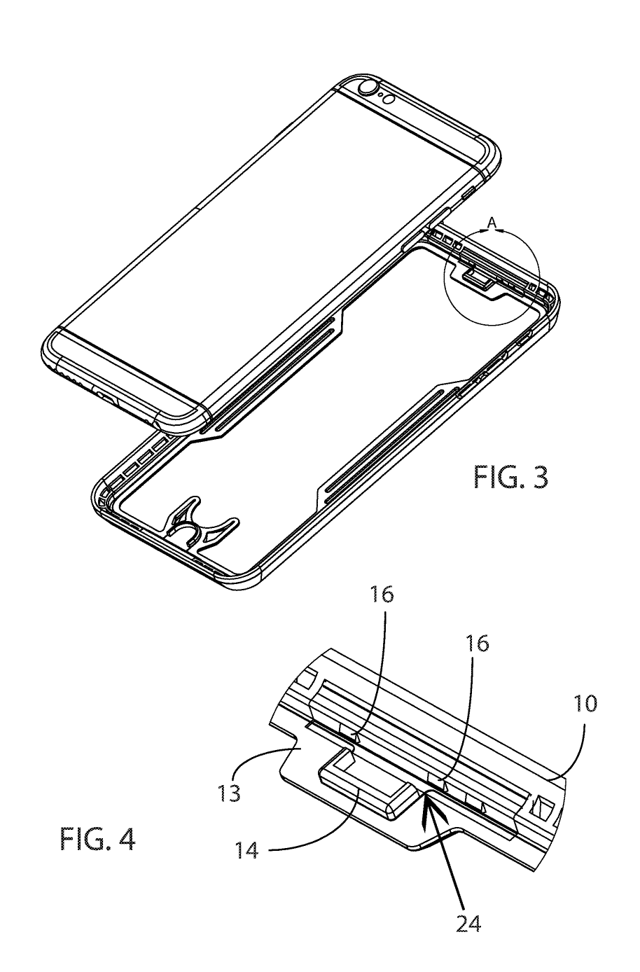

The uniform fit of the frame 10 and screen protector 20 is achieved by geometrically controlling the fit of the screen protector 20 and device 30 to the frame 10. One method is to provide blocks, such as the two depicted blocks 12, 14 in the frame 10 which comport with cutouts 22, 24 of the screen protector 20 (FIGS. 3-6), which as stated before comport with features of the device 30. Frame 10 may also present a plurality of clip teeth 16 which secure the screen protector 20 in the frame and, when either the screen protector 20 is properly mounted therein or then installed on the device 30, the interaction of the screen protector 20 with the clip teeth 16 provides an audible click to signal completed stages of application. The screen protector 20 may be held against a rim 17 of the frame 30. Such a rim 17 may present projections 11, 13 which may extend over the front surface of the screen protector 20 and may support the blocks 12, 14. Other projections, such as side projections 15, may be provided for additional support of a screen protector 20. Other features, such as storage loop 18, may be provided.

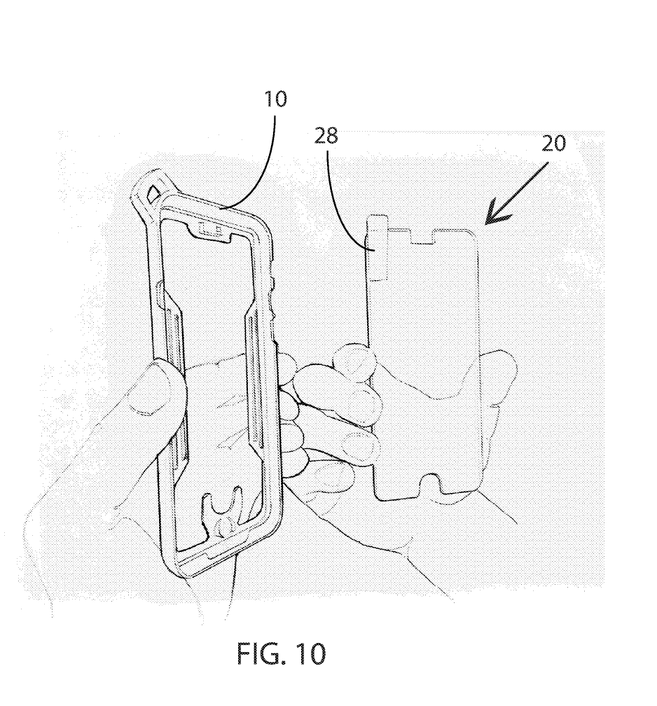

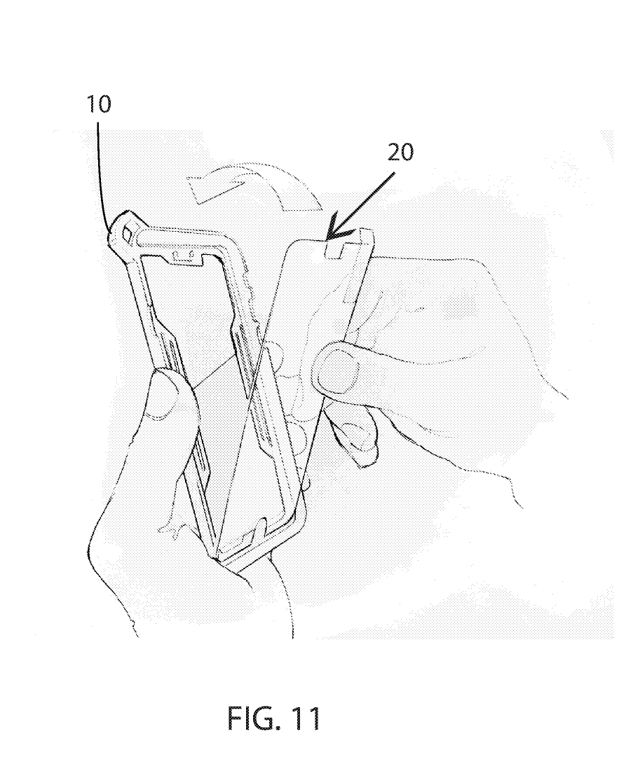

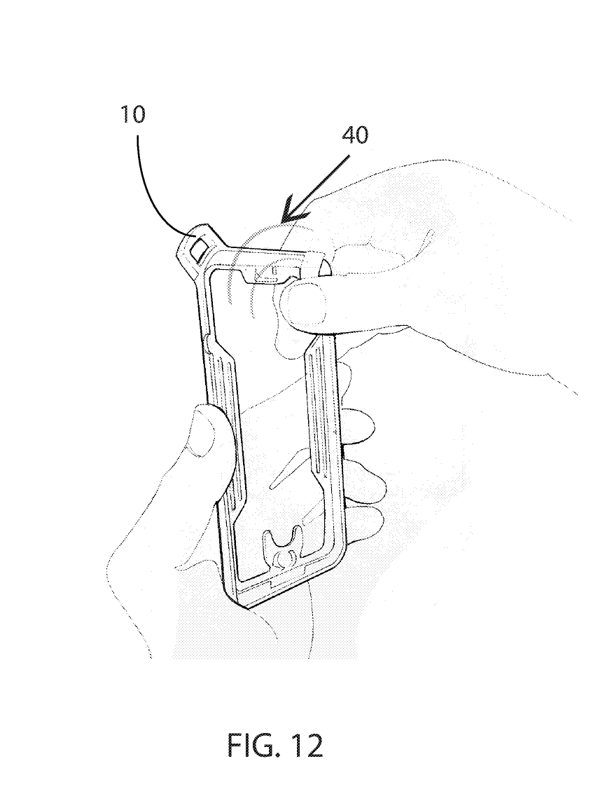

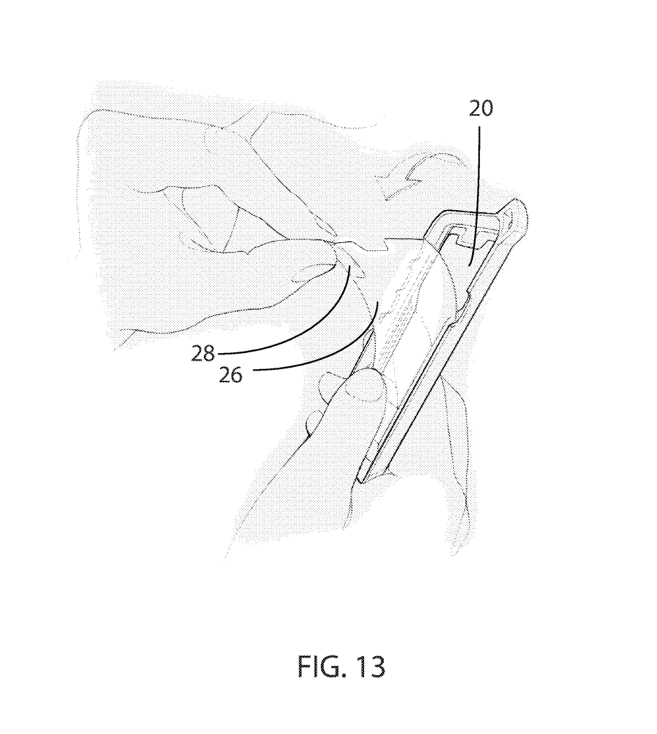

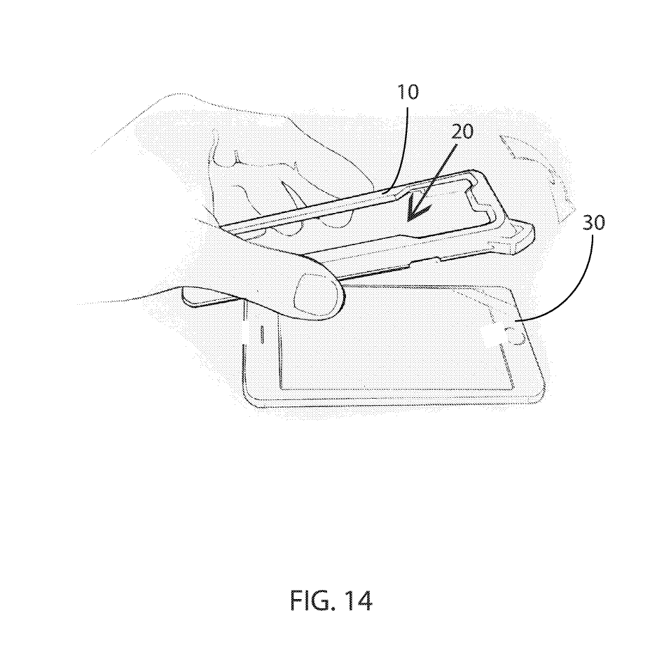

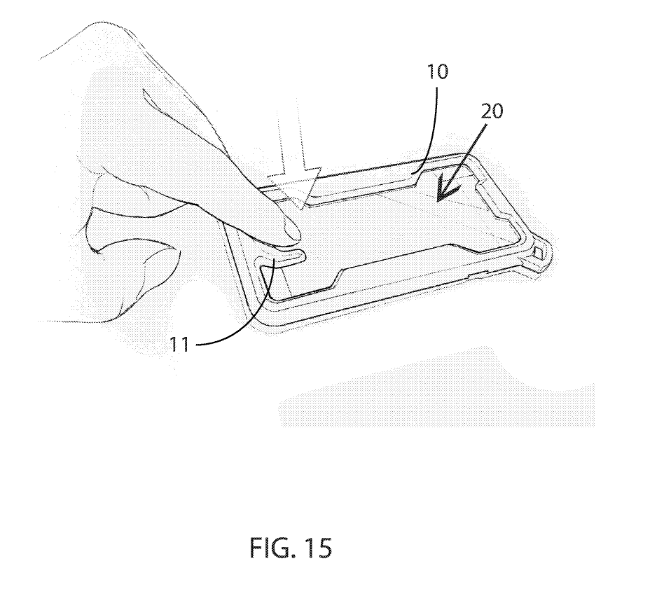

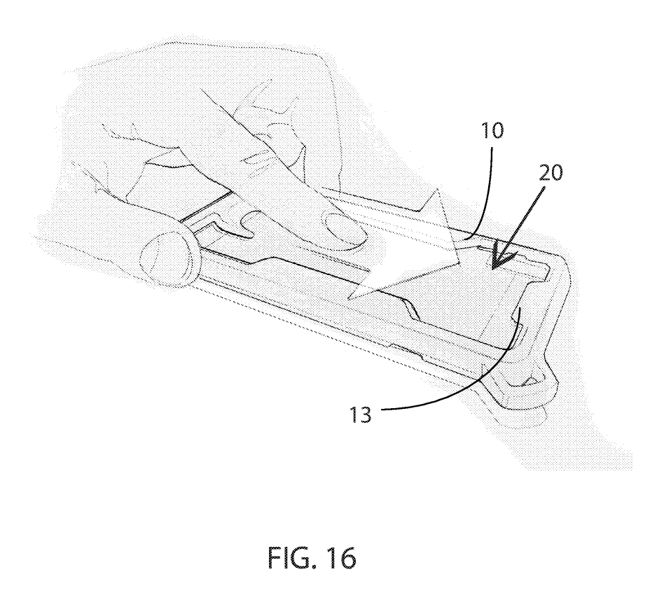

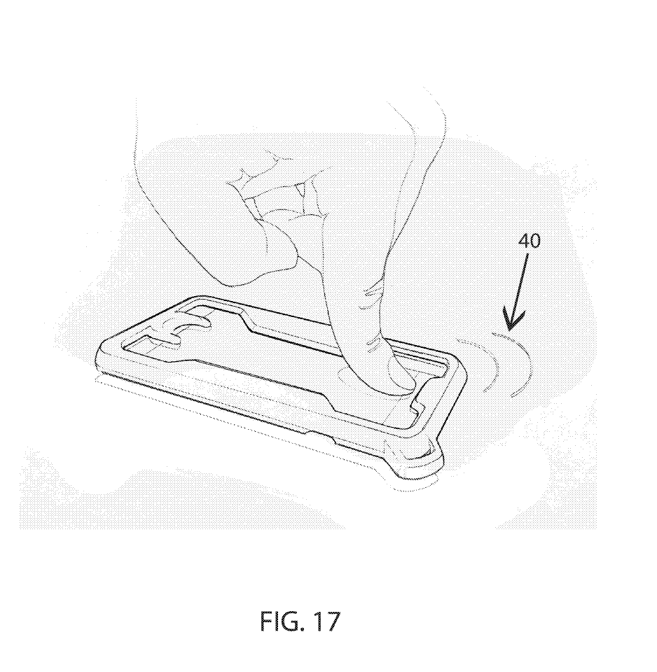

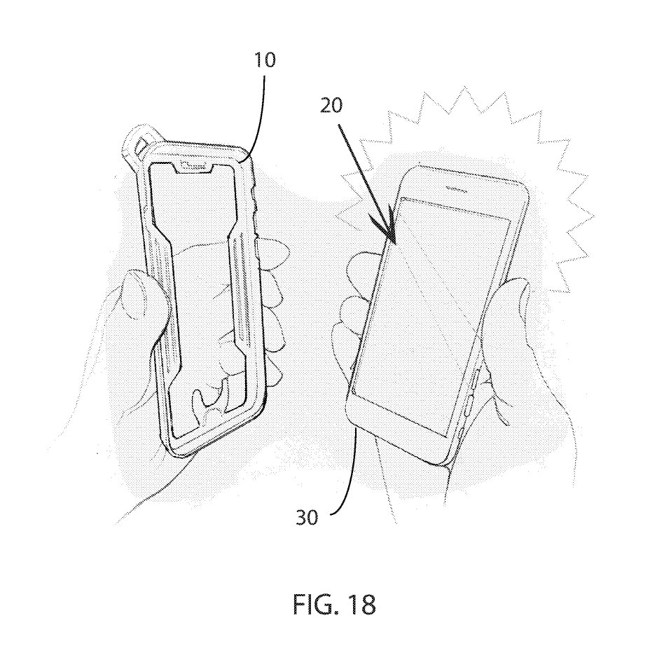

Installation of the screen protector is accomplished by first mounting the screen protector 20 in the frame (FIGS. 10-12). The protector is aligned within the frame 10 and pressed into position. An audible click 40 indicates successful mounting (FIG. 12). Ideally, each protector 20 is provided with a release liner 26 and pull tab 28 (FIG. 13). The release liner 26 covers the screen protector's adhesive until it is ready for installation. When mounted in the frame 10, the pull tab 28 is drawn to remove the release liner 26 and expose the adhesive. Then the frame is positioned over the device 30 (FIG. 14). Since both protector 20 and device 30 may only fit in the frame 10 at pre-appointed orientations, the protector 20 and device 30 will always have the same spacial relationship with each other. It should be noted that one of the illustrated projections 11 is divided into two branches. This projection 11 and its branches may then indicate and provide a starting point for the user to place a finger or other useful tool at the projection 11 for final installation (FIG. 15). If constructed with a block 12, the user would then be placing instant force about where the first cutout in the screen protector 20. The user then draws the finger upwards (FIG. 16), in this case towards the opposite projection 13, until the screen protector drops onto the device with another audible click (FIG. 17). Use of the longitudinal direction is sensible in that there is greater allowed flex in the protector 20 with the longer distance; but, it should be readily appreciated that the direction of motion is generally arbitrary. Directional indicia may also be applied to the frame 10 and the projections 11, 13 may provide an instinctual indicator of direction. The frame 10 may then be removed (FIG. 18) leaving the screen protector 20 on the device 30. At that time, any further treatment, such as more thoroughly applying pressure and removing air bubbles, may be instituted.

Although the present invention has been described with reference to preferred embodiments, numerous modifications and variations can be made and still the result will come within the scope of the invention. No limitation with respect to the specific embodiments disclosed herein is intended or should be inferred.

What is claimed is:

1. A system for applying a screen protector to a given device, the system comprising:
a. a screen protector designed to fit and comport with the given device;
b. a frame designed to entirely encompass the given device while also containing and holding the entire screen protector above a screen surface of the device; and
c. a means of releasing the screen protector, from its initial position over the device to a final position on the device;
wherein the frame always positions a new screen protector and a new device in the same relative positions such that each new screen protector is always positioned at the same relative location on the screen surface of the new device.

2. The system of claim 1, the screen protector having at least one hole and the frame having at least one block to comport with said at least one hole, the at least one hole comporting with at least one feature on the device.

3. The system of claim 2, the frame having at least one projection from which the at least one block originates, the at least one projection extending over a top surface of the screen protector when it is installed in the frame.

4. The system of claim 3, the at least one projection indicating a starting point to apply pressure to the screen protector so as to release the screen protector and install it upon the given device.

5. The system of claim 3, the frame comprising a plurality of clip teeth which suspend the screen protector above the device, wherein pressure from above the frame and screen protector release the screen protector from the plurality of clip teeth.

6. The system of claim 2, the frame comprising a plurality of clip teeth which suspend the screen protector above the device, wherein pressure from above the frame and screen protector release the screen protector from the plurality of clip teeth.

7. The system of claim 1, the frame comprising a plurality of clip teeth which suspend the screen protector above the device, wherein pressure from above the frame and screen protector release the screen protector from the plurality of clip teeth.

8. A method of applying a rigid screen protector to a device, the method comprising:
a. placing the screen protector into a provided frame, said frame totally encompassing the screen protector;
b. placing a given device into the provided frame, said frame totally encompassing the given device and also holding the screen protector over a surface of the given device;
c. applying pressure to the screen protector to release the screen protector from the frame in a manner to drop it precisely on the top surface of the given device.

9. The method of claim 8, the frame utilizing clips to secure the screen protector over the surface of the given device, said clips and screen protector interacting to provide an audible sound when the screen protector is properly installed in the frame and when the screen protector is properly released from the same.

10. The method of claim 8, the frame providing an indication of a starting point at which to initially apply pressure to the screen protector.
